(19) United States
(12) Patent Application Publication
(10) Pub. No.: US 2003/0157781 A1
(43) Pub. Date: Aug. 21, 2003

(54) Method of filling trenches

(76) Inventors: John Macneil, Cardiff (GB); Knut Beekman, N. Somerset (GB); Tony Wilby, Bristol (GB)

Correspondence Address: Volentine Francos, Suite 150, 12200 Sunrise Valley Drive, Reston, VA, 20191, US

(21) Appl. No.: 10/220,800

(22) PCT Filed: Jan. 21, 2002
(86) PCT No.: PCT/GB02/00241

(30) Foreign Application Priority Data
Jan. 20, 2001 (GB) 0101528.8

(51) Int. Cl. H01L 21/44; H01L 21/76

(52) U.S. Cl. 438/424; 438/660; 438/436

(57) ABSTRACT

This invention relates to a method of filling at least one trench or other opening in a substrate including depositing a dielectric material into the trench or opening and annealing the deposited material during or after the application of pressure. The process may be stepwise and the anneal step may at least include or be followed by the exposure of the substrate to an H₂ plasma.

This invention relates to a method of filling trenches and other openings in a substrate, such as a semiconductor wafer.

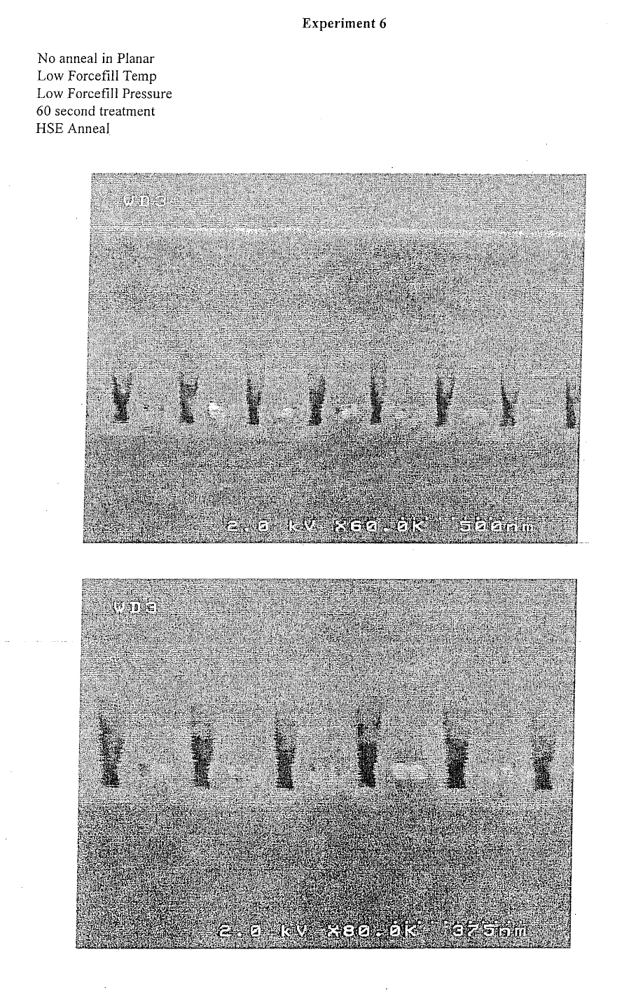

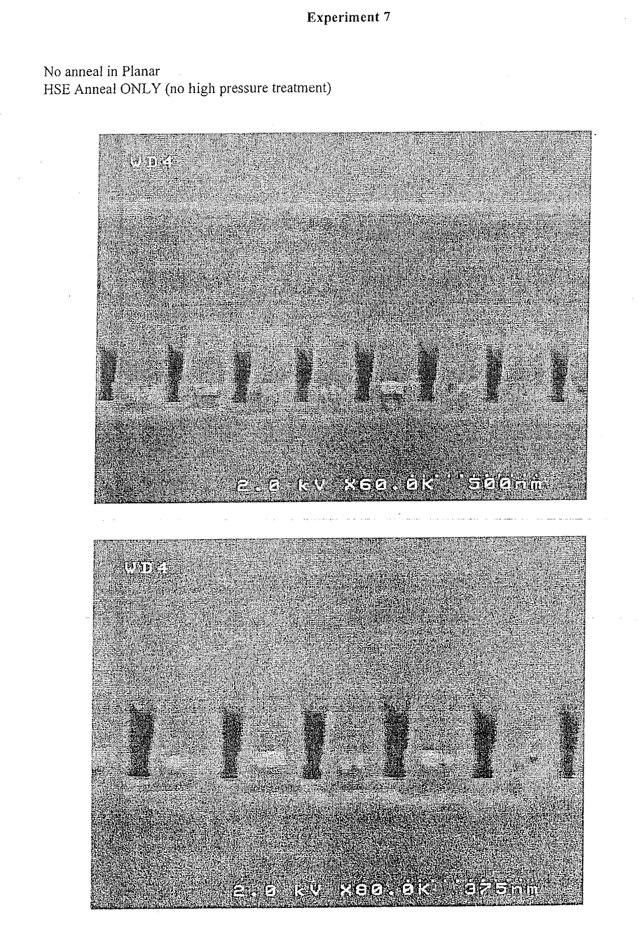

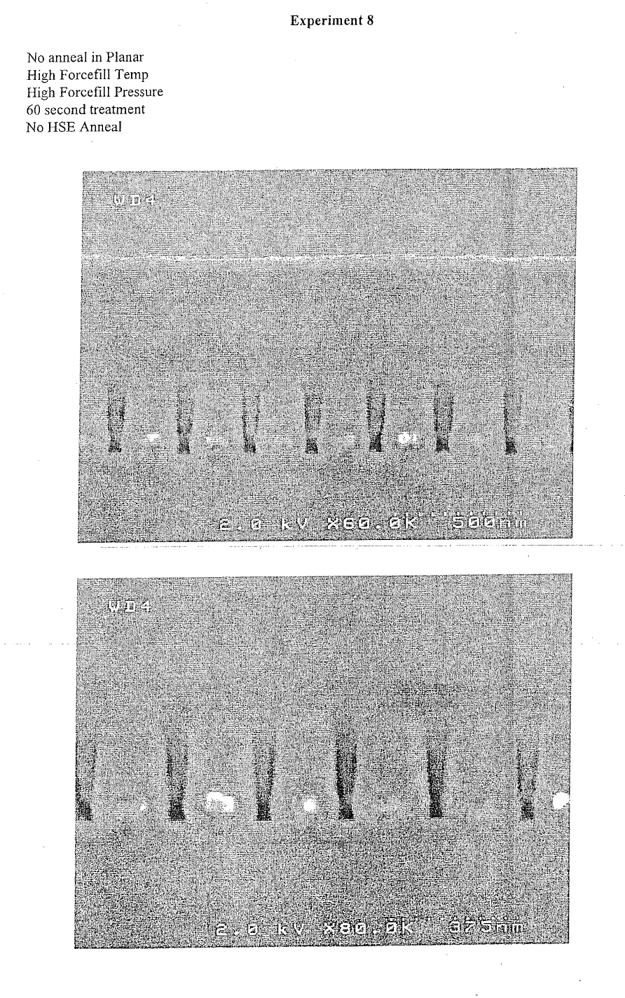

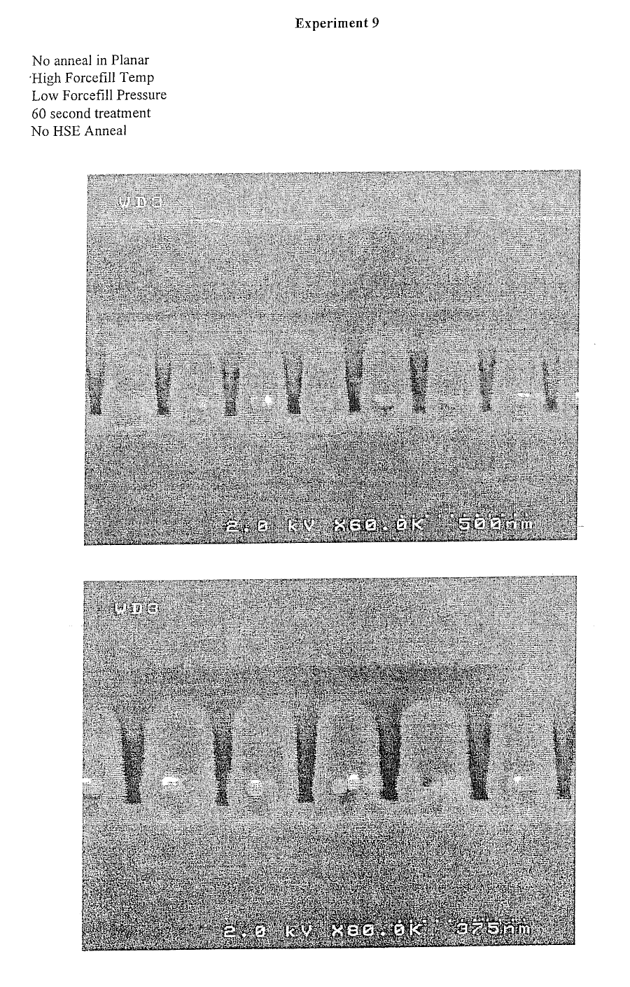

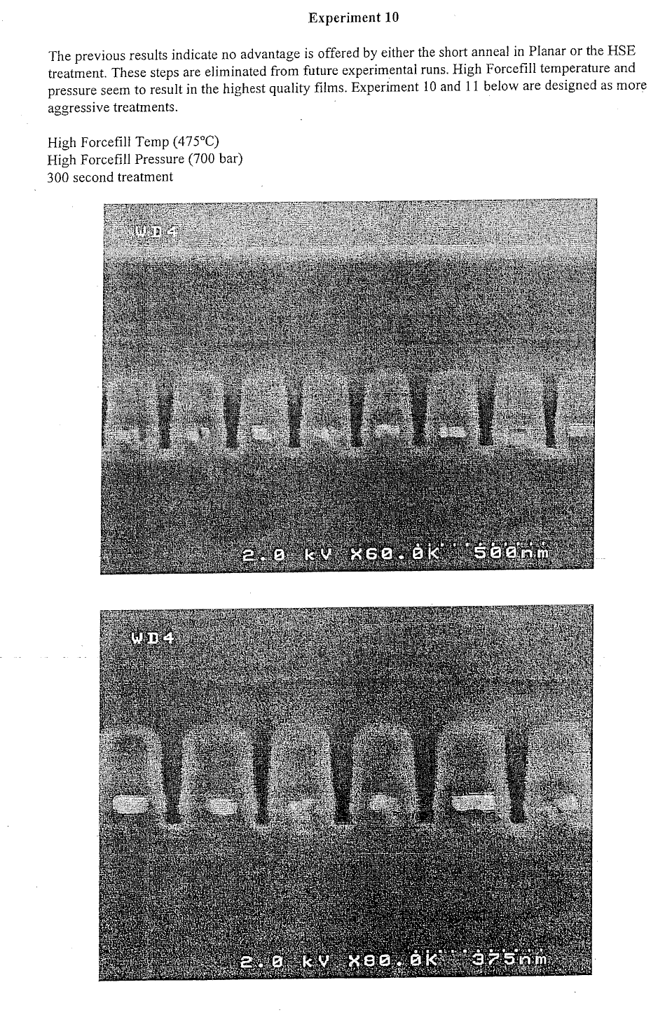

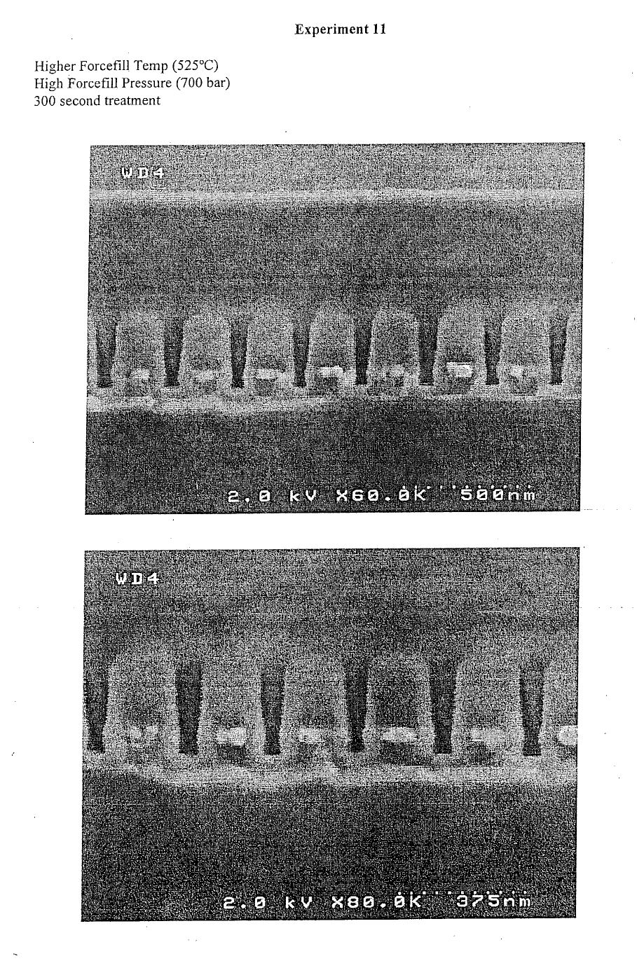

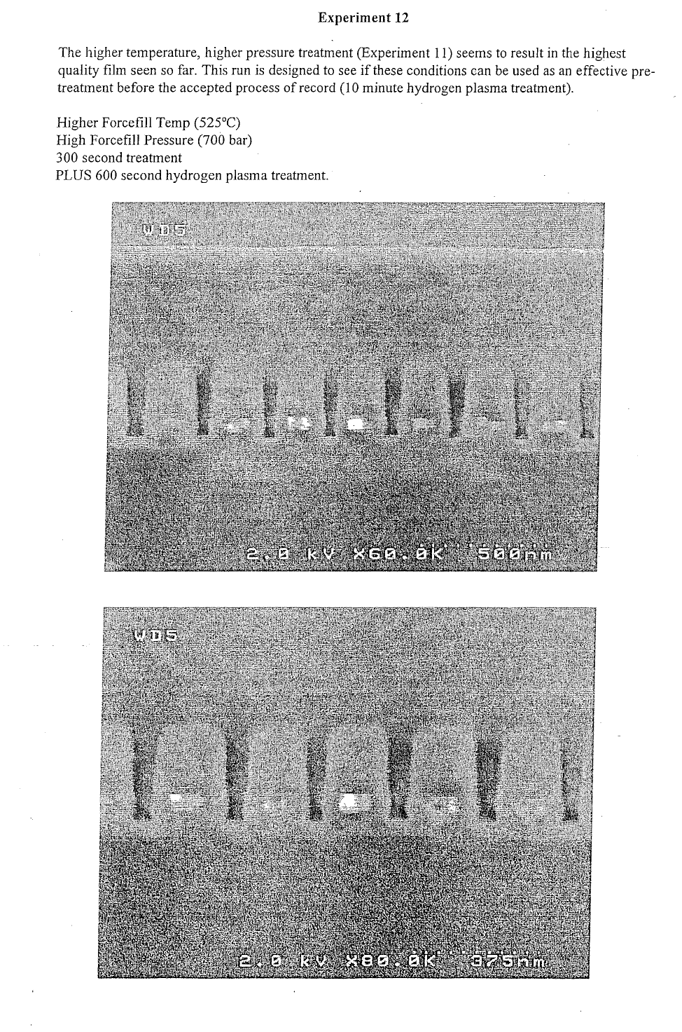

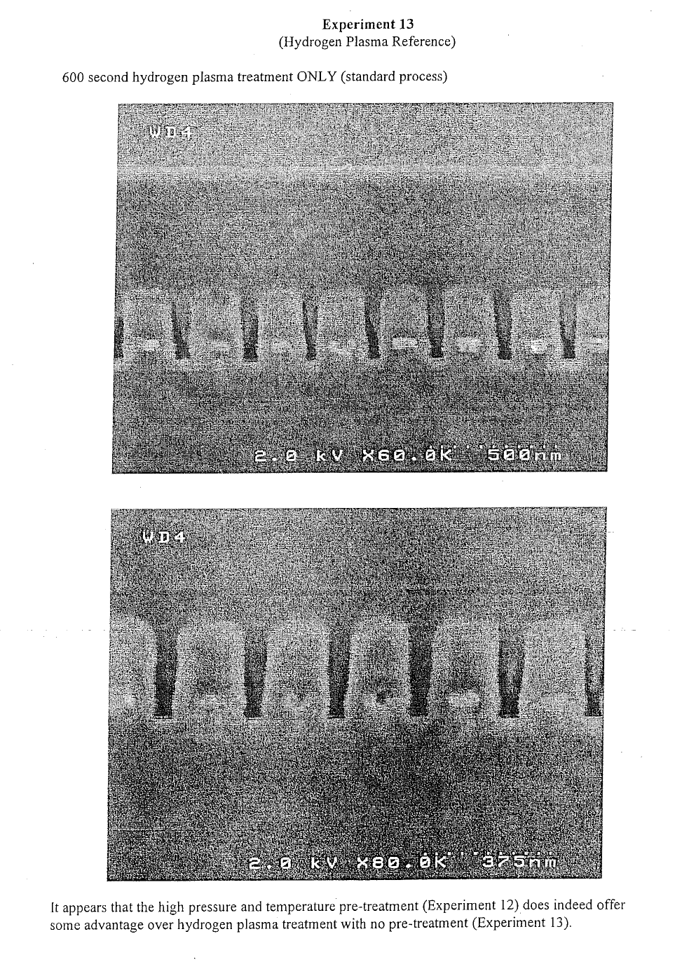

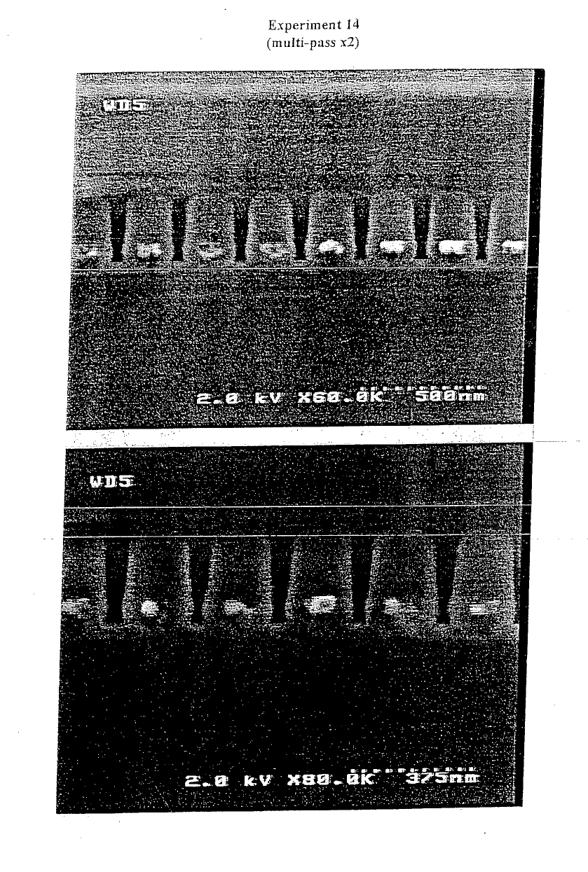

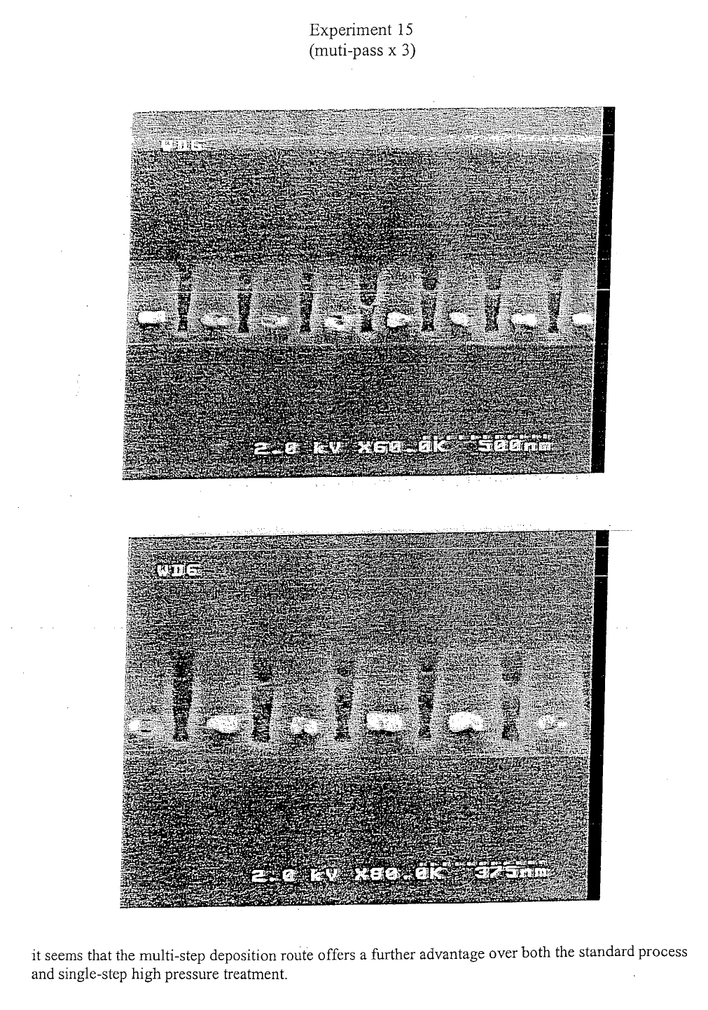

In certain processes, such as the construction of shallow trench isolation features and the formation of pre-metal dielectric for semiconductor devices, there is a need to achieve dense films in small gaps. However, when the film is deposited within those gaps, there is frequently a requirement to remove water from the as-deposited film and, where that film is in a sub micron wide recess, the result is that voids are formed and the material often has an undesirably low density. Thus, even when there is complete filling, the density of the material may be low, which means that it is highly susceptible to being etched. For shallow trench isolation, this is particularly problematic because the material is preferably resistant to wet etching and the filled trench should stand proud after wet stripping of field layers of oxide and nitride, for example as shown in FIGS. 4 and 5 of U.S. Pat. No. 5,447,884.

The present invention consists in a method of filling at least a trench or other opening in a substrate, for example a semiconductor wafer, including depositing a dielectric material into the trench or opening, applying pressure to the deposited material and annealing the deposited material during or after the application of pressure.

The trench or opening may be completely filled or, preferably, the trench or opening may initially be partially filled and the deposited material subjected to pressure or pressure and anneal. The trench or opening may then be completely filled by one or more further deposition steps and pressure and pressure or annealing may take place after one or more of the further deposition steps.

The anneal step may at least include or be followed by the exposure of the substrate to an H₂ plasma.

The applied pressure should be sufficient to effect the process. Experiments were performed at 100 and 700 bar. The pressure should be applied for an effective time period. The experiments were performed for 60 and 300 seconds.

The substrate may be heated before or during the application of pressure. In this case the substrate may be heated to between about 150° C. and about 550° C. Preferably the substrate temperature is about 475° C. to 525° C.

Although the invention has been defined above, it is to be understood it includes any inventive combination of the features set out above or in the following description.

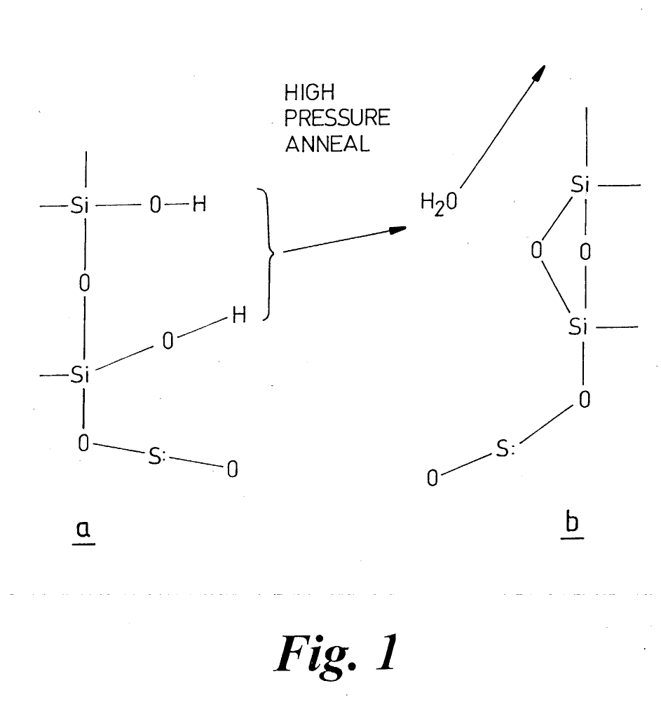

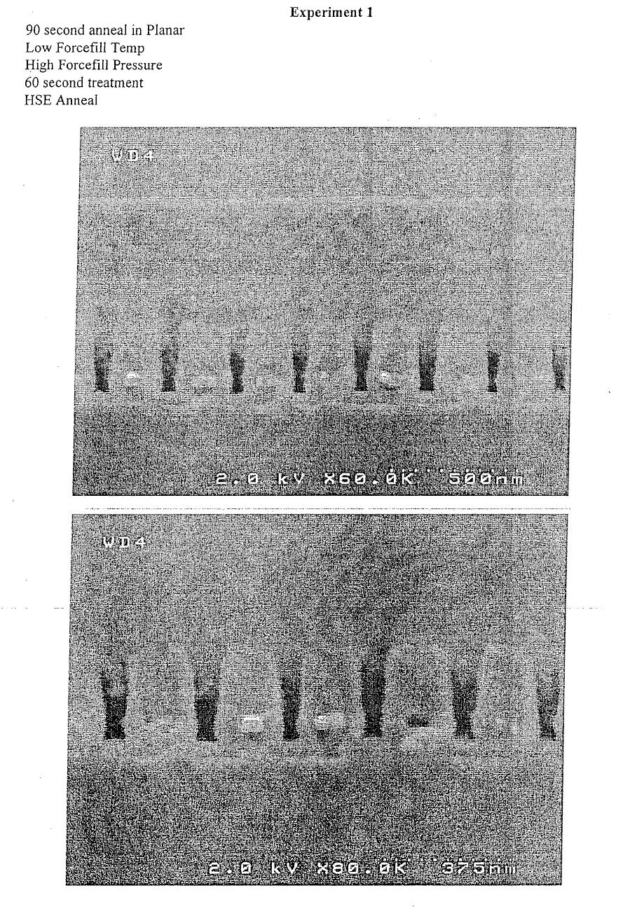

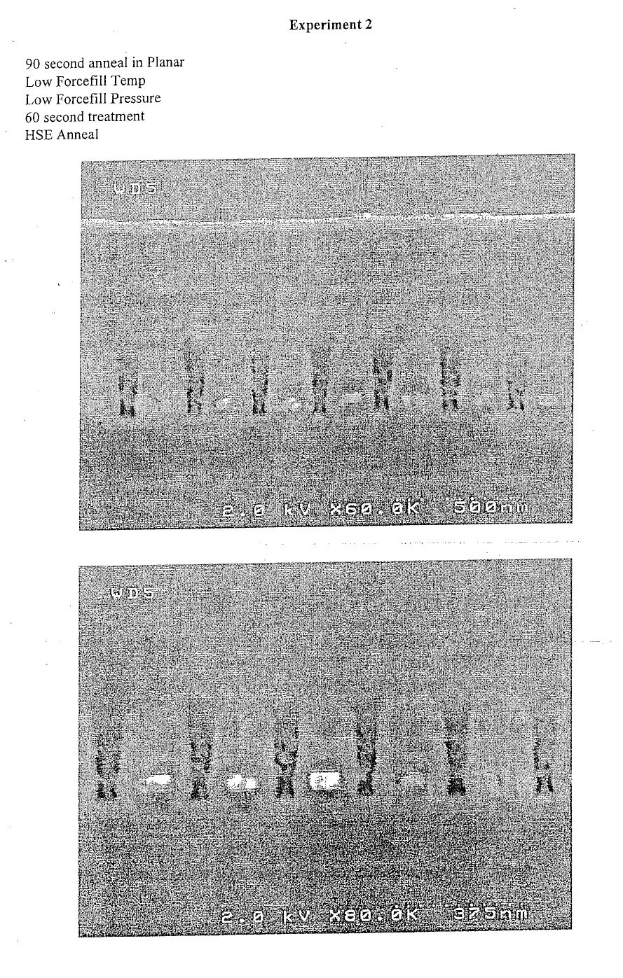

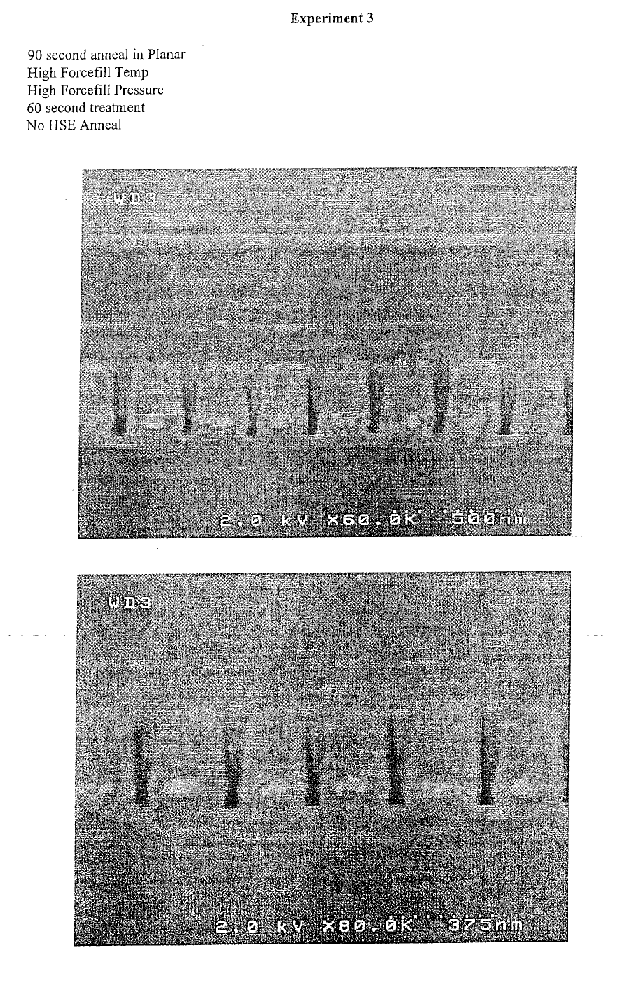

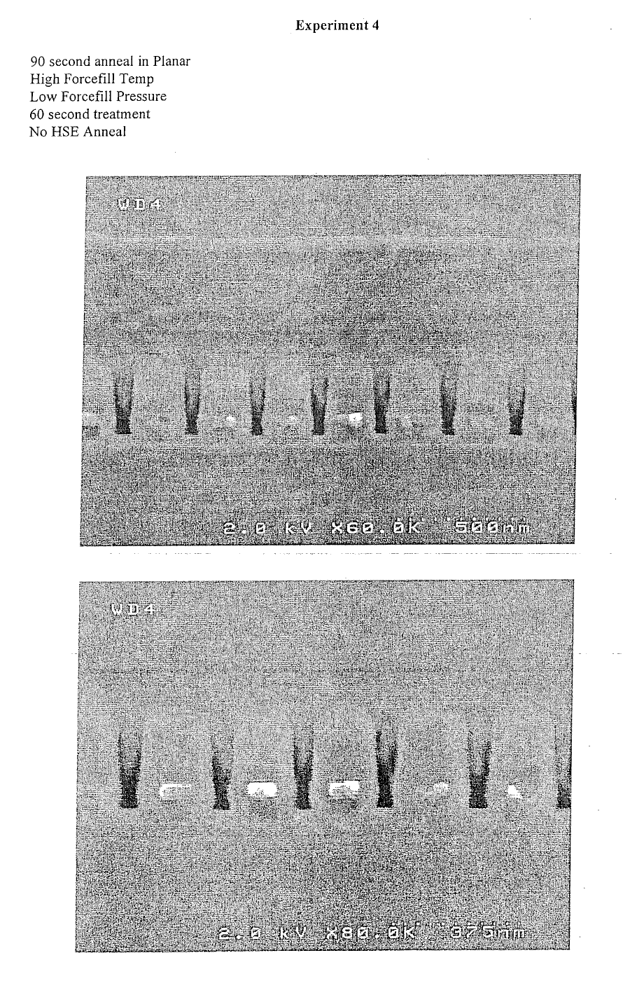

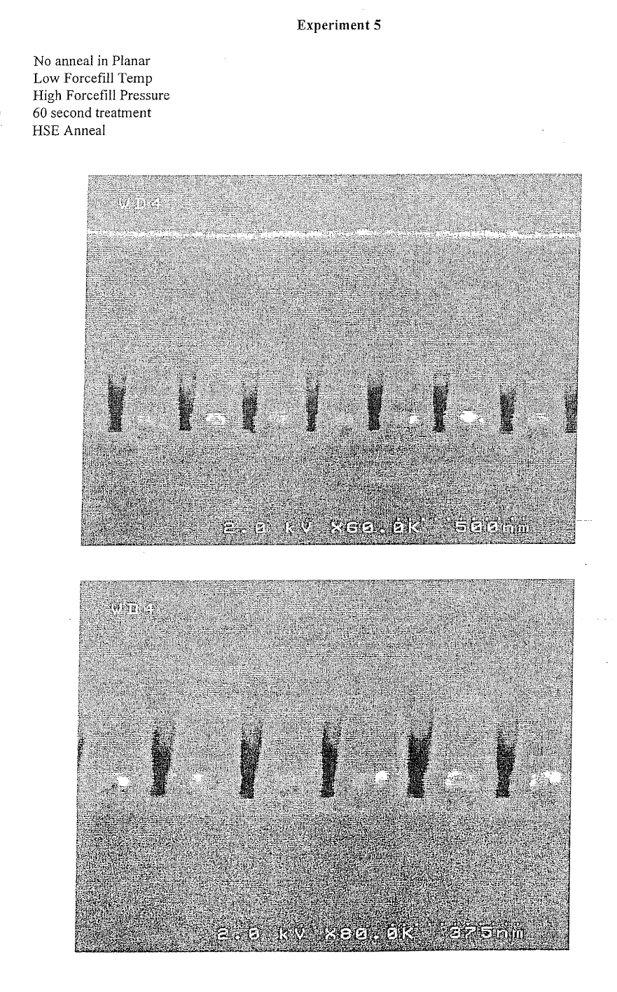

The invention may be performed in various ways and specific embodiments will now be described in connection with the duly designated scanning electron micrographs attached hereto and FIG. 1, which illustrates the affect of pressure on an anneal process whereby isolated O—H are forced together by the application of high pressure, thus assisting the thermally induced removal of water. Experiments 3, 4, 7 to 11 and 13 are comparative examples.

In each experiment a film was deposited using the applicant's Flowfill® process in which a liquid silanol is deposited by a condensation reaction and is subsequently hardened to form an oxide film using an anneal process. The reference to Flowfill® deposition is accordingly in the following description simply a reference to the deposition process. An example of such a deposition process is described in U.S. Pat. No. 5,874,367. References to Planar™ relate to the equipment for performing the Flowfill® process and this apparatus is also described in that US patent. U.S. Pat. No. 5,527,561 describes pressure application apparatus of the type suitable to perform a high pressure process, although the actual apparatus described can apply pressures to significantly higher values and a more simplistic apparatus may also be suitable. These patents are incorporated herein by reference.

With this background, a method of increasing the density of dielectric films deposited in small gaps is described. These gaps are typically less than 100 nm (1,000 Å) wide and with an aspect ratio (depth to width) of greater than 3. More particularly they are gaps of less than 50nm (500A) width with an aspect ratio greater than 5. The dielectric is deposited using the Flowfill® process onto wafers and may be used for a shallow trench isolation (STI) process or to form a pre-metal dielectric (PMD). The experiments were performed on wafers containing test features consisting of SiN trenches that are around 40 nm (400 Å) wide and 360 nm (3600 Å) deep.

The Flowfill® process can fill these gaps with a liquid silanol by a condensation reaction which is then hardened to form an oxide film. This hardening normally occurs during a low-pressure (sub-atmospheric pressure) thermal or plasma ‘anneal’. This process results in an oxide film that is of lower density in narrow trenches than in the bulk. A ‘delineation’ etch of a cleaved sample will show voiding within gaps resulting from the rapid etch of low density dielectric. A method is described where the density of the film can be improved in small gaps by performing a multi-step high pressure and temperature anneal prior to hydrogen plasma treatment.

The invention is in using high pressure with heat to mechanically assist water removal from a silanol or silanol like layer. At the time of writing there is no single layer methodology (including that reported here) that is capable of filling such small gaps (sub 100 nanometer) with high quality dielectric (ones that do not show voiding when delineated with 10:1 buffered HF etch). The application of pressure is shown to improve results. The only entirely successful results required at least two layers to be deposited into the void with a high pressure anneal on the first layer, before the second layer was deposited. The gaps under consideration here are considerably smaller than in the prior art and whilst it is not experimentally reported here, plasma treatments in general use, hydrogen plasma treatments, and pure thermal anneals will not sufficiently densify the dielectric layer even when carried out on multiple thin layers e.g. as reported in IBM technical disclosure bulletin nr.11 volume 27 of April 1985. Gaps in current use on the most advanced semiconductor wafers are typically somewhere between 0.35 and 0.13 microns (350 to 130 nanometers). Conventional plasma treatments and thermal treatments are reported to not work sufficiently well on single layer films into 0.35 micron gaps. This high pressure process in contrast, is able to sufficiently densify single layer films at these larger gap widths. It should be noted that the STI/PMD gap depths do not change greatly as the widths decrease. So as widths decrease, aspect ratios increase and the ratio of contained volume to exposed surface area increases.

### PROCESS STEPS

All experiments were performed on cleaved pieces of wafer. The following summarize the possible process steps considered:

| Process Step | | |
|---|---|---|
| And sequence | | System |
| 1. N₂O plasma treatment | ALWAYS | Planar ™ |
| 2. 2000Å Flowfill ® deposition | ALWAYS | Planar |
| 3. Low pressure ‘soft’ Anneal | OPTIONAL | Planar |
| 4. High pressure treatment | OPTIONAL | Forcefill ® |
| 5. Low pressure Anneal | OPTIONAL | Forcefill ® |
| 6. Hydrogen plasma | OPTIONAL | Planar |
| 7. 4000Å cap deposition | ALWAYS | Planar |

Experiments were performed with existing systems labelled Planar™ and Forcefill®. These are single wafer cluster systems, where Planar is a CVD system including plasma pretreatments, CVD deposition and thermal and plasma post treatments with wafer transportation under vacuum. Forcefill is a high-pressure single wafer cluster system usually associated with metal deformation to fill wafer recesses. This chamber was not mounted onto the Planar system and therefore wafers were exposed to ambient atmosphere between systems for the process sequences described. This is not believed to be significant to the experiments.

Process Description
1. N₂O plasma treatment:

| | |
|---|---|
| Temperature of platen | 450° C. |
| Process time | 20 seconds |
| Pressure | 1400 m Torr |
| N₂O | 3500 sccm |
| N₂ | 1500 sccm |
| Power to showerhead | 500 W @ 375 kHz |

A plasma process to form a ‘base’ silicon dioxide layer by plasma treating the bare silicon and thereby improving adhesion.

2. Flowfill deposition

| | |
|---|---|
| Temperature of platen | 0° C. |
| Process time | as required |
| Pressure | 850 m Torr |
| SiH₄ | 120 sccm |
| N₂ | 300 sccm |
| H₂O₂ | 0.65 g/min |
| Power to showerhead | 500 W @ 375 kHz. |

The process for depositing the water containing polymer or silanol. A spin-on water containing polymer could be substituted

3. soft bake:

| | |
|---|---|
| Temperature of platen | 450° C. |
| Process time | 90 seconds |
| Pressure | 20 m Torr |

A ‘soft’ thermal anneal at low pressure under a pure nitrogen ambient in the Planar system (vacuum wafer transport from the deposition chamber). Note that due to the low pressure the wafer temperature does not reach platen temperature. Wafers exit from this chamber at approximately 190° C. This process step is found to avoid ‘blistering’ when Flowfill and cap layers are annealed conventionally e.g. 30 minutes at 450° C., nitrogen ambient at atmospheric pressure. For STI/PMD applications (before metal interconnect present on the wafer) anneal temperatures can be above 450° C.

4. High Pressure Treatment

Described in table below.

This was carried out in a different system from the deposition.

5. Anneal

| | |
|---|---|
| Process temperature | 450° C. |
| Process time | 180 seconds |
| Pressure | 1 Torr |

Thermal anneal carried out in the Forcefill system. This is a pure nitrogen anneal at sub-atmospheric pressure sufficient to assist thermal transfer from platen to wafer.

6. Hydrogen Plasma:

| | |
|---|---|
| Temperature of platen | 400° C. |
| Process time | 600 seconds |
| H₂ | 1000 sccm |
| Power to the showerhead | 1000 W @ 13.56 MHz |

7. Cap deposition

| | |
|---|---|
| Temperature of platen | 450° C. |
| Thickness | 4000Å |
| Pressure | 750 m Torr |
| SiH4 | 100 sccm |
| N₂ | 1000 sccm |
| N₂O | 2000 sccm |
| Power to showerhead | 500 W @ 375 kHz |

The experimental runs are described in the table below being a matrix of the optional process steps for treating the as-deposited film(s)

| Process step | 3. | 4. High Pressure Treatment | | | | |
|---|---|---|---|---|---|---|
| Experiment | Planar | Temp | Pressure | Time | 5. | 6. |
| Number | Anneal | (° C.) | (bar) | (secs) | Anneal | H2 plasma |
| 1 | YES | 180 | 700 | 60 | YES | NO |
| 2 | YES | 180 | 100 | 60 | YES | NO |
| 3 | YES | 475 | 700 | 60 | NO | NO |
| 4 | YES | 475 | 100 | 60 | NO | NO |
| 5 | NO | 180 | 700 | 60 | YES | NO |
| 6 | NO | 180 | 100 | 60 | YES | NO |
| 7 | NO | N/A | N/A | 0 | YES | NO |
| 8 | NO | 475 | 700 | 60 | NO | NO |
| 9 | NO | 475 | 100 | 60 | NO | NO |
| 10 | NO | 475 | 700 | 300 | NO | NO |
| 11 | NO | 525 | 700 | 300 | NO | NO |
| 12 | NO | 525 | 700 | 300 | NO | YES |
| 13 | NO | N/A | N/A | 0 | NO | YES |

In addition to determine if a multi-step deposition of the Flowfill followed by pressure treatment is advantageous the following two experiments were run. High pressure treatment used is the same as that used in Experiment 12 above.

Experiment 14

| Step | Process | System |
|---|---|---|
| 1 | N₂O plasma treatment | Planar |
| 2 | 800Å Flowfill deposition | Planar |
| 3 | High pressure treatment | Forcefill |
| 4 | N₂O plasma treatment | Planar |
| 5 | 800Å Flowfill deposition | Planar |
| 6 | High pressure treatment | Forcefill |
| 7 | Hydrogen plasma | Planar |
| 8 | 4000Å Cap deposition | Planar |

Experiment 15

| Step | Process | System |
|---|---|---|
| 1 | N₂O plasma treatment | Planar |
| 2 | 300Å Flowfill deposition | Planar |
| 3 | High pressure treatment | Forcefill |
| 4 | N₂O plasma treatment | Planar |
| 5 | 300Å Flowfill deposition | Planar |
| 6 | High pressure treatment | Forcefill |
| 7 | N₂O plasma treatment | Planar |
| 8 | 300Å Flowfill deposition | Planar |
| 9 | High pressure treatment | Forcefill |
| 10 | Hydrogen Plasma | Planar |
| 11 | 4000Å Cap deposition | Planar |

In the above cases the Flowfill thickness measurements are the depth deposited on the field of the substrate, not actually in the trench. In practice it appears that some material deposited on the field flows into the trenches, so that the total thickness deposited in the field may be less than the total depth of the trench.

Scanning electron micrographs (SEM) were made of a cleaved edge of a patterned wafer that has been delineated in 10:1 BHF for 2 seconds at 20° C. Visual inspection yielded the following summary of the results:

All processes that included either a high pressure anneal and/or a hydrogen plasma were better than only a low pressure thermal anneal. Low pressure (standard) thermal anneal only (450° C.) shows the worst quality film in the gaps.

Experiment 12 (high pressure anneal and hydrogen plasma treatment) gave the best result for single film depositions. This was an improvement over the ‘process of record’ being experiment 13, which gives the next best result.

A ‘soft’ bake before, or low pressure anneal after high pressure anneal show no great influence on the high pressure anneal results.

High pressure anneal temperatures of 475° C. show an improvement over 180° C. however 525° C. shows no significant difference compared to 475° C.

Higher pressure (700 bar) would appear to be slightly more favourable for the high pressure treatment (anneal).

Increased time of the high pressure treatment step did not have a major effect in the range tested (60 to 300 seconds), indicating that temperature and pressure are more important than time at temperature and time at pressure.

It is therefore to be expected that a shorter process time than 60 seconds would achieve water removal on at least some films for some wafer features, this shorter time being preferable for economic reasons.

Single film depositions can be improved upon if layers are deposited such that they only partially fill the recess and are then treated. In experiment 14 the Flowfill was deposited in two steps (800 Å each), with high pressure anneal and H₂ plasma treatments after each step. No significant improvement was noted over a single film deposition due to the first Flowfill step being sufficient to completely fill the gap (the Flowfill layer, being liquid, will fill recesses deeper than its nominal thickness), the second deposition then being upon the field of the wafer. In experiment 15 more than one thin layer was deposited and treated to fill the gap. This gave the best result overall. It is therefore demonstrated that there is a benefit in densifying the film prior to completely filling the gap.

1. A method of filling at least one trench or other opening in a substrate including depositing a dielectric material into the trench or opening and annealing the deposited material during or after the application of pressure.

2. A method as claimed in claim 1 wherein the trench or opening is initially partially filled and the deposited material subject to pressure or pressure and anneal and the trench or opening is then completely filled by one or more further deposition steps.

3. A method as claimed in claim 2 or claim 3 wherein the material deposited in the second or subsequent steps is subjected to pressure and/or anneal.

4. A method as claimed in any one of the preceding claims wherein the anneal step at least includes or is followed by the exposure of the substrate to an H₂ plasma.

5. A method as claimed in any one of the preceding claims wherein the pressure applied is above 100 bar.

6. A method as claimed in claim 6 wherein the pressure is about 700 bar.

7. A method as claimed in any one of the preceding claims wherein the pressure is applied for about 1 to about 300 seconds.

8. A method as claimed in claim 8 wherein the pressure is applied for about 60 seconds.

9. A method as claimed in any one of the preceding claims wherein the substrate is heated before or during the application of pressure.

10. A method as claimed in claim 10 wherein the substrate is heated to between about 150° C. and about 550° C.

11. A method as claimed in claim 10 wherein the substrate temperature is about 475° C.-525° C.

12. A method as claimed in anyone of the preceding claims wherein the dielectric layer is a silanol or silanol like layer.
